(19) United States
(12) Patent Application Publication
(10) Pub. No.: US 2024/0206101 A1
(43) Pub. Date: Jun. 20, 2024

(54) FACEPLATE AND ELECTRONIC DEVICE

(71) Applicant: FANUC CORPORATION, Minamitsuru-gun, Yamanashi (JP)

(72) Inventor: Daisuke MIURA, Minamitsuru-gun, Yamanashi-ken (JP)

(73) Assignee: FANUC CORPORATION, Minamitsuru-gun, Yamanashi (JP)

(21) Appl. No.: 18/286,647

(22) PCT Filed: Apr. 13, 2021
(86) PCT No.: PCT/JP2021/015335

§ 371 Date: Oct. 12, 2023

(51) Int. Cl. H05K 7/14; H05K 7/20

(52) U.S. Cl. CPC H05K 7/1417; H05K 7/1427; H05K 7/1452; H05K 7/20145

(57) ABSTRACT

Provided are a faceplate for suppressing the flow of air entering and exiting an electronic device through a gap, and the electronic device provided with the faceplate. The faceplate covering an opening of a slot of the electronic device when a circuit board is inserted into the slot comprises: a main body plate that covers the opening of the slot; an opening portion that is formed in the main body plate and exposes a connecting surface side of a connector provided at the circuit board by allowing the connecting surface side of the connector to be inserted therein; and a suppressing member that suppresses the flow of air in the gap between the opening portion and the connector.

### TECHNICAL FIELD

The present invention relates to a faceplate to be attached to a slot for accommodating a board, and an electronic device including the faceplate.

### BACKGROUND ART

An electronic device including a slot, a circuit board accommodated in the slot, and a fan unit for air-cooling the circuit board is known (JP 2019-186373 A).

### SUMMARY OF THE INVENTION

The cooling air for cooling the circuit board is taken in from the intake opening of the electronic device by the fan unit, cools the circuit board in the casing of the electronic device, and is then exhausted from the exhaust opening. At this time, if air other than the cooling air enters through a gap formed in the casing, there arises a possibility that the efficiency of cooling the circuit board is adversely affected.

As a specific example of the gap, a gap related to an opening which is provided in a faceplate and through which a connector is exposed is disclosed in JP 2019-186373 A. In the electronic device disclosed in JP 2019-186373 A, a gap is formed between the opening of the faceplate and the connector. There is a possibility that air other than the cooling air enters the electronic device through the gap.

An object of the present invention is to provide a faceplate that suppresses a flow of air flowing into and out of an electronic device through a gap, and an electronic device provided with the faceplate.

A first aspect of the present invention is a faceplate to which a circuit board is attached and which covers an opening of a slot of an electronic device when the circuit board is inserted into the slot, the faceplate comprising: a main body plate configured to cover an opening of the slot; an opening portion which is formed in the main body plate and into which a connection surface side of a connector provided on the circuit board is inserted to expose the connection surface side of the connector; and a suppression member configured to suppress a flow of air in a gap formed between the opening portion and the connector.

A second aspect of the present invention comprises: a casing provided with an intake opening configured to take in cooling air, a slot into which a circuit board to be cooled by the cooling air is inserted, and an exhaust opening through which the cooling air having cooled the circuit board is exhausted; and a faceplate to which the circuit board is attached, wherein the faceplate includes: a main body plate configured to cover an opening of the slot; an opening portion which is formed in the main body plate and into which a connection surface side of a connector provided on the circuit board is inserted to expose the connection surface side of the connector; and a suppression member configured to suppress a flow of air in a gap formed between the opening portion and the connector.

According to the present invention, there are provided a faceplate that suppresses a flow of air flowing into and out of an electronic device through a gap, and an electronic device provided with the faceplate.

### BRIEF DESCRIPTION OF DRAWINGS

FIG. 1 is a rear perspective view of an electronic device according to an embodiment;

FIG. 2 is a perspective view showing a faceplate according to the embodiment;

FIG. 3A is a cross-sectional view taken along line IIIA-IIIA of FIG. 2;

FIG. 3B is a view showing a state in which the faceplate is attached to a circuit board in FIG. 3A;

FIG. 4 is a perspective view showing the faceplate according to a first modification;

FIG. 5A is a cross-sectional view taken along line VA-VA of FIG. 4;

FIG. 5B is a view showing a state in which a second connector is inserted into an opening portion in FIG. 5A;

FIG. 6 is a view showing a further modified example of suppression members of FIG. 5A;

FIG. 7 is a perspective view showing the faceplate according to a second modification;

FIG. 8A is a cross-sectional view taken along line VIIIA-VIIIA of FIG. 7;

FIG. 8B is a view showing a state in which the second connector is inserted into the opening portion in FIG. 8A; and

FIG. 9 is a view for explaining the faceplate according to a third modification.

### DETAILED DESCRIPTION OF THE INVENTION

A preferred embodiment of a faceplate and an electronic device of the present invention will be described in detail below with reference to the accompanying drawings.

### Embodiment

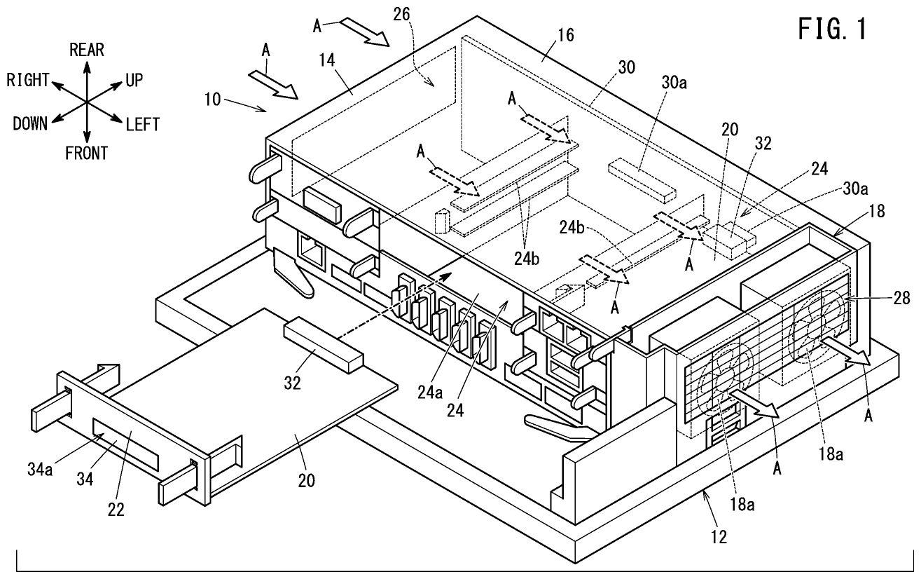

FIG. 1 is a rear perspective view of an electronic device 10 according to an embodiment.

In FIG. 1, the directions (front, rear, left, right, up, and down) used in the description are indicated by arrows. The front-rear direction, the left-right direction, and the up-down direction are orthogonal to each other. The directions indicated by arrows in the other drawings correspond to the directions shown in FIG. 1.

The electronic device 10 is, for example, a numerical controller, and is provided to an operator to control an industrial machine such as a machine tool or a robot. The electronic device 10 of FIG. 1 includes an indicator 12, and a control unit 14 disposed rearward of the indicator 12.

Although not shown, the indicator 12 includes a liquid crystal display screen on the front side thereof, and displays information on the display screen. The indicator 12 is connected to the control unit 14. Note that the material of the display screen is not limited to liquid crystal and may be changed as appropriate.

The control unit 14 includes a casing 16, a fan unit 18, a plurality of circuit boards 20 accommodated in the casing 16, and a faceplate 22 attached to each of the plurality of circuit boards 20. In FIG. 1, only one circuit board 20 is shown for illustrative purposes.

The casing 16 is provided with a plurality of slots 24 in which the plurality of circuit boards 20 are accommodated, an intake opening 26 for taking cooling air A into the casing 16, and an exhaust opening 28 for exhausting the cooling air A taken from the intake opening 26.

The slots 24 are formed by partitioning the inside of the casing 16 by partitions. FIG. 1 illustrates the plurality of slots 24 each extending upward from the bottom side on which an opening 24a is provided. Each of the plurality of slots 24 can be provided with guide rails 24b for guiding the circuit board 20 to the inner side. A backboard 30 is provided at the innermost portion of each slot 24. In the example of FIG. 1, the “inner side” refers to the upper side. The circuit board 20 is inserted into each of the plurality of slots 24 from the opening 24a toward the inner side of the slot 24.

The intake opening 26 is provided on the right part of the casing 16 in the example of FIG. 1, but it is not particularly limited thereto. On the other hand, the exhaust opening 28 is provided on the left part of the casing 16 in the example of FIG. 1, but it is not limited thereto as well. The intake opening 26 and the exhaust opening 28 may each include, as appropriate, an adjustment member (for example, a damper) for adjusting the volume of the cooling air A.

The fan unit 18 includes rotating fans 18a. The cooling air A is taken into the casing 16 from the intake opening 26 by the rotation of the fans 18a, and is exhausted from the exhaust opening 28. The cooling air A cools the plurality of circuit boards 20 inserted into the plurality of slots 24 between the intake opening 26 and the exhaust opening 28.

A predetermined electric circuit is appropriately formed on each of the plurality of circuit boards 20 accommodated in the plurality of slots 24. This electric circuit controls, for example, the above-mentioned indicator 12, or controls, for example, the industrial machine.

Each of the plurality of circuit boards 20 on the side of an insertion direction of the circuit board 20 (the upward direction in FIG. 1) is provided with a first connector 32 for electrical connection with the backboard 30. In this regard, the backboard 30 is provided with board-side connectors 30a for connection with the first connectors 32. The plurality of circuit boards 20 are communicably connected to each other through the backboard 30 by the connection between the first connectors 32 and the board-side connectors 30a. The backboard 30 is also connected to the indicator 12, and the plurality of circuit boards 20 are communicably connected to the indicator 12 through the backboard 30.

Further, each of the plurality of circuit boards 20 on the side of a direction opposite to the insertion direction, that is, a take-out direction of the circuit board 20 from the slot 24 (the downward direction in FIG. 1) is provided with a second connector 34 and is attached with the above-described faceplate 22.

The second connector 34 serves as a connector that is connected to an external interface outside the casing 16 so as to communicably connect the external interface to the circuit board 20, and as a result, to the backboard 30. The external interface is connected to the second connector 34 on the take-out direction side. For this reason, hereinafter, the take-out direction side of the second connector 34 is also referred to as a “connection surface side 34a”.

The faceplate 22 is a member for exposing the second connector 34 from the inside of the casing 16 to the outside of the casing 16, while covering the opening 24a of the slot 24 accommodating the circuit board 20. The faceplate 22 preferably includes a material that imparts a deformable property to the faceplate 22 for reasons discussed below. For illustrative purposes, the faceplate 22 of the present embodiment is configured to include an elastic resin material.

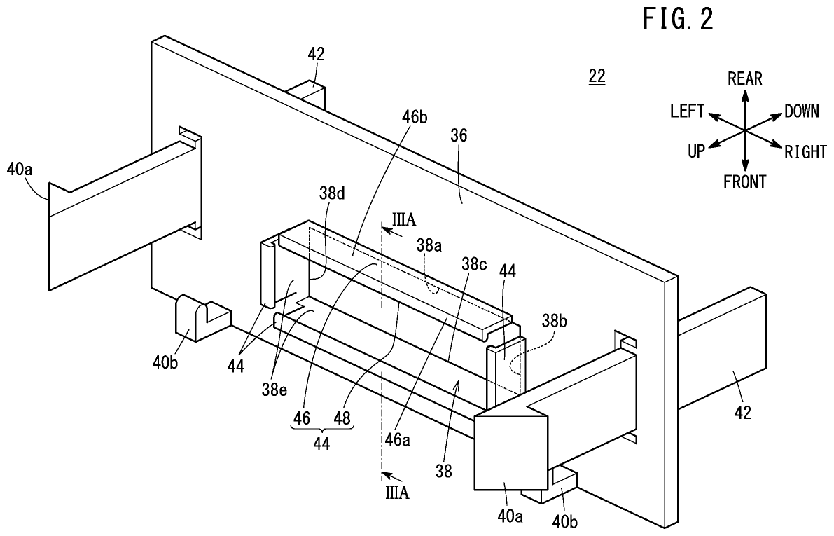

FIG. 2 is a perspective view showing the faceplate 22 according to the embodiment.

As shown in FIG. 2, the faceplate 22 includes a substantially flat main body plate 36, an opening portion 38 into which the second connector 34 is inserted, claws 40a and 40b provided at the main body plate 36 on the side (the upward direction side) on which the circuit board 20 is attached, and tabs 42 provided on the opposite side thereto (the downward direction side).

The main body plate 36 is a plate-shaped member that covers the opening 24a of the slot 24 (see FIG. 1). The opening portion 38 is formed in the main body plate 36 in order to expose the connection surface side 34a of the second connector 34. The shape of the opening portion 38 is not particularly limited, but is set to be quadrangular in FIG. 2 for illustrative purposes. Therefore, the opening portion 38 in FIG. 2 is bordered by four sides (38a, 38b, 38c, and 38d).

The claws 40a are used for attaching the faceplate 22 to the casing 16. Accordingly, locking portions on which the claws 40a are hooked and locked are preferably provided in the casing 16, as appropriate.

The claws 40b are used for attaching the faceplate 22 to the circuit board 20. Accordingly, locking portions for locking the claws 40b are preferably provided in the circuit board 20, as appropriate.

The tabs 42 are gripped by the operator when the circuit board 20 is taken out from the casing 16. The operator can easily take out the circuit board 20 from the slot 24 by gripping the tabs 42 and pulling them in the take-out direction.

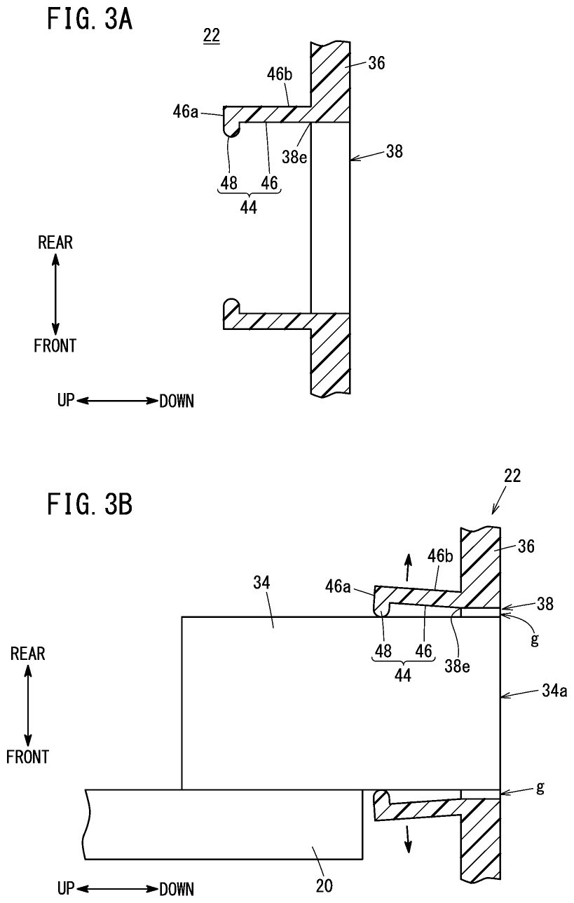

FIG. 3A is a cross-sectional view taken along line IIIA-IIIA of FIG. 2. FIG. 3B shows a state in which the faceplate 22 is attached to the circuit board 20 in FIG. 3A.

The faceplate 22 of the present embodiment further includes suppression members 44. The suppression members 44 each include an extending portion 46 extending in the insertion direction of the circuit board 20 (the upward direction) from the main body plate 36 toward the inside of the electronic device 10, and a protruding portion 48 protruding from the extending portion 46 toward the second connector 34 (toward the inside of the opening portion 38).

The faceplate 22 is attached to the circuit board 20 by locking the circuit board 20 with the above-mentioned claws 40b, and at this time, as shown in FIG. 3B, the second connector 34 provided on the circuit board 20 is inserted into the opening portion 38 of the faceplate 22. The protruding portions 48 are provided so as to interfere with the second connector 34 when the second connector 34 is inserted into the opening portion 38. Therefore, when the second connector 34 is inserted into the opening portion 38, the extending portions 46 are elastically deformed in accordance with the insertion. Due to this elastic deformation, the possibility that the insertion of the second connector 34 into the opening portion 38 is greatly hindered by the interference is reduced.

With the suppression members 44, it is possible to suppress deterioration of the cooling efficiency of the electronic device 10. That is, as shown in FIG. 3B, when the second connector 34 is inserted into the opening portion 38, a gap g is formed between the opening portion 38 and the second connector 34. If air (for example, warm air) other than the cooling air A enters the slot 24 through the gap g, the efficiency of cooling the circuit board 20 by the cooling air A may be deteriorated. In this regard, in the present embodiment, the passage of air extending from the gap g between the opening portion 38 and the second connector 34 to the inside of the casing 16 is restricted by the suppression members 44 provided around the opening portion 38. As a result, the flow of air in the gap g is suppressed, and deterioration of the cooling efficiency of the electronic device 10 is suppressed.

In the present embodiment, after the second connector 34 is inserted into the opening portion 38, an elastic restoring force acts on the extending portions 46. Accordingly, the protruding portions 48 come into close contact with the second connector 34. As a result, the protruding portions 48 suitably inhibit the flow, along the insertion direction, of the air entering through the gap g.

When the opening portion 38 has a quadrangular shape as in the present embodiment, the suppression member 44 may be provided for each of the four sides (38a, 38b, 38c, and 38d) bordering the quadrangular shape (see FIG. 2). As a result, it is possible to suitably restrict the passage of the air.

In the example of the present embodiment, each of the extending portions 46 is provided such that a base end thereof is an edge 38e of the opening portion 38, but the base end of the extending portion 46 is not limited to the edge 38e as long as the extending portion 46 extends from the main body plate 36 toward the inside of the electronic device 10. In addition, in the example of the present embodiment, each of the protruding portions 48 protrudes from a distal end 46a of the extending portion 46, but the protruding portion 48 may protrude from the middle (an intermediate portion 46b) of the extending portion 46.

According to the present embodiment, it is possible to suppress the flow of air in the gap g while generating the gap g. In other words, if it is desired to prevent air from flowing into and out of the casing 16 through the gap g, the gap g itself may be eliminated. However, it is not realistic to completely eliminate the gap g (to always set the tolerance of the second connector 34 and the faceplate 22 to 0) in actual manufacturing. In addition, if there is no gap g at all, then there is no margin between the opening portion 38 and the second connector 34, and thus it is difficult to insert the second connector 34 into the opening portion 38. Therefore, in consideration of workability at the time of manufacturing, it is rather undesirable that there is no gap g at all.

Thus, in the present embodiment, as described above, while the small gap g is allowed to occur between the opening portion 38 and the second connector 34, the flow of air in the gap g is suppressed by the suppression members 44 having a simple configuration provided in the faceplate 22. As a result, in the present embodiment, it is possible to ensure the workability in manufacturing the faceplate 22 while achieving the good cooling efficiency of the electronic device 10 when the user (operator) uses the electronic device 10.

### Modifications

The embodiment has been described above as one example of the present invention. It goes without saying that various modifications or improvements are capable of being added to the above-described embodiment. Further, it is clear from the scope of the claims that other modes to which such modifications or improvements have been added can be included within the technical scope of the present invention.

Hereinafter, a description will be given of some specific examples concerning modifications according to the embodiment. However, components already described in the embodiment are denoted by the same reference numerals as in the embodiment. In addition, differences from the embodiment will be mainly described below, and redundant description will be omitted as much as possible.

### Modification 1

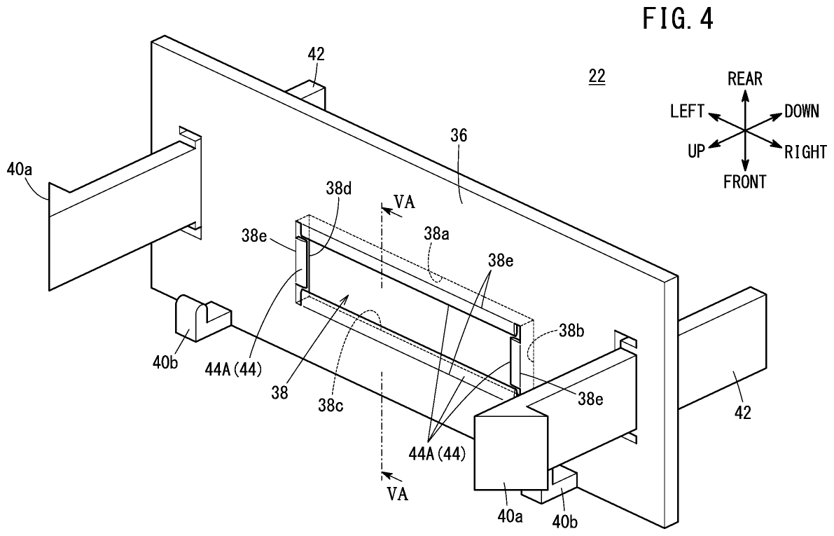

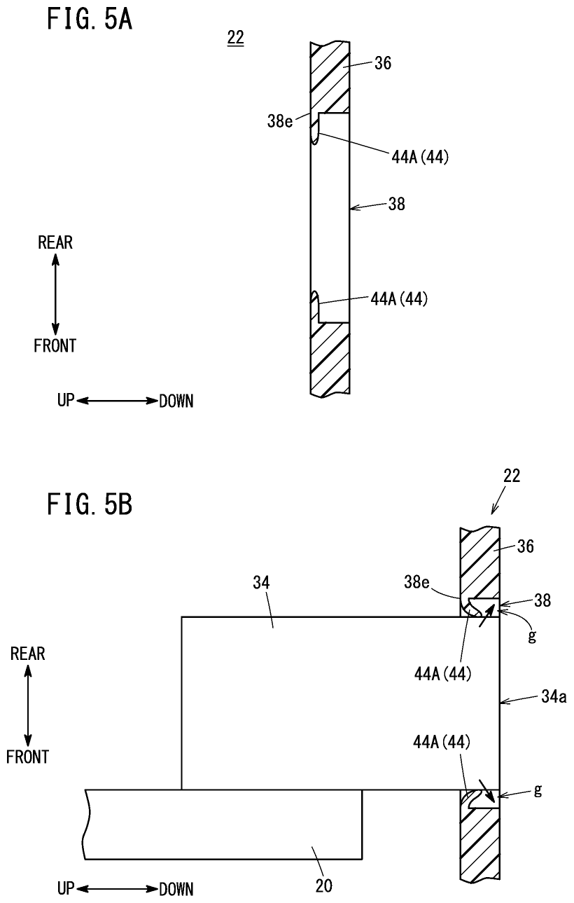

FIG. 4 is a perspective view showing the faceplate 22 according to a first modification. FIG. 5A is a cross-sectional view taken along line VA-VA of FIG. 4. FIG. 5B is a view showing a state in which the second connector 34 is inserted into the opening portion 38 in FIG. 5A.

The faceplate 22 may be provided with suppression members 44 (44A) each extending from the edge 38e of the opening portion 38 toward the inside of the opening portion 38. By interfering with the second connector 34 inserted into the opening portion 38, the suppression members 44A are deformed so as to be warped toward the side of the insertion direction of the second connector 34 (see FIG. 5B). Thus, also in the present modification, the suppression members 44A do not hinder the operation of inserting the second connector 34 into the opening portion 38 during manufacture, and can suppress the flow of air in the gap g during use of the electronic device 10.

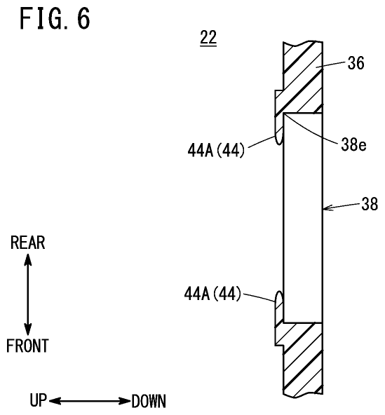

FIG. 6 is a view showing a further modified example of the suppression members 44A of FIG. 5A.

The suppression members 44A of this modified example may each be provided so as to extend from the edge 38e of the opening portion 38 toward the second connector 34. In other words, as illustrated in FIG. 6, the suppression members 44A need not be provided in the opening portion 38 as long as the suppression members 44A each extend from the edge 38e toward the second connector 34.

### Modification 2

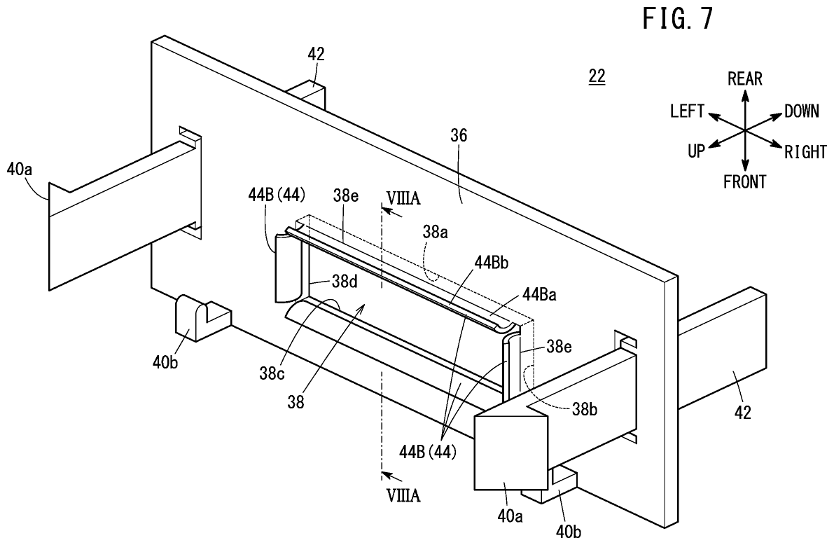

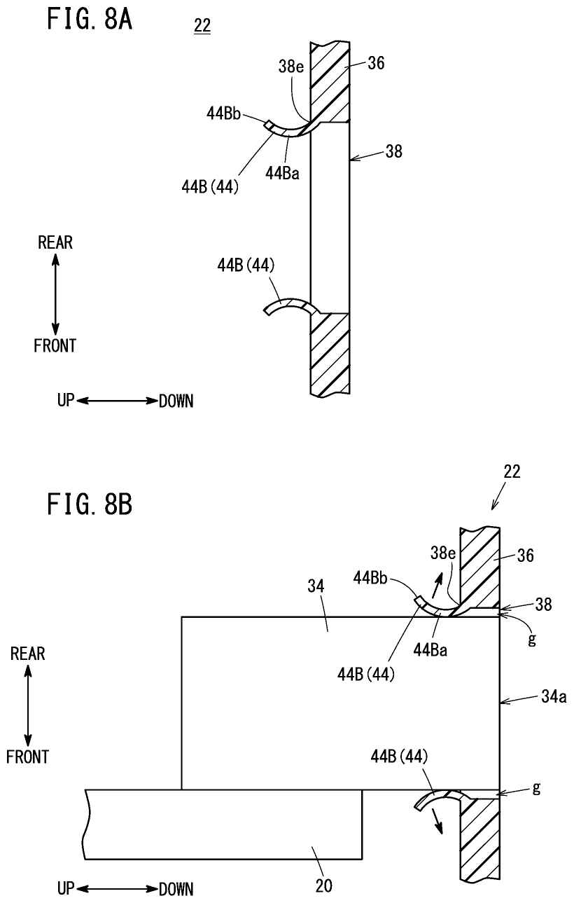

FIG. 7 is a perspective view showing the faceplate 22 according to a second modification. FIG. 8A is a cross-sectional view taken along line VIIIA-VIIIA of FIG. 7. FIG. 8B is a view showing a state in which the second connector 34 is inserted into the opening portion 38 in FIG. 8A.

Although the suppression members 44A extending toward the inside of the opening portion 38 have been described in the first modification, suppression members 44 (44B) as shown in FIG. 7 may be provided in the faceplate 22. Each of the suppression members 44B extends from the main body plate 36 toward the inside of the electronic device 10 and has a curved shape such that an intermediate portion 44Ba thereof protrudes toward the connector.

A tip 44Bb of the suppression member 44B is oriented in a direction opposite to the direction toward second connector 34. As a result, the suppression members 44B function as guides for inserting the second connector 34 into the opening portion 38.

### Modification 3

The faceplate 22 (the suppression members 44) may be made of a plastic material. That is, although the suppression members 44 are elastically deformed in the embodiment, the suppression members 44 may be plastically deformed. This will be described below.

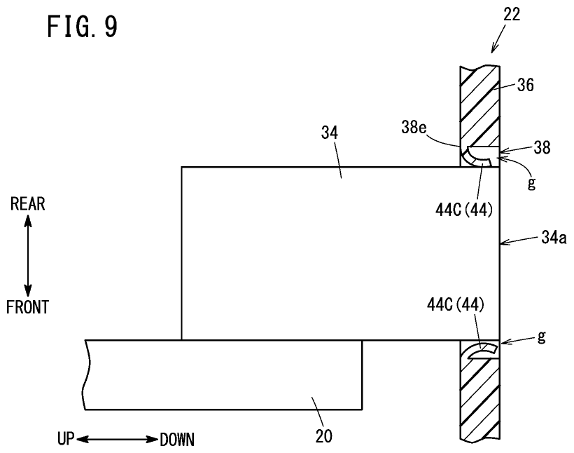

FIG. 9 is a view for explaining the faceplate 22 according to a third modification.

Suppression members 44C of FIG. 9 are an example of the suppression members 44 having plasticity. When the second connector 34 is inserted into the opening portion 38, the suppression members 44C can be plastically deformed by interference with the second connector 34. Therefore, the suppression members 44C do not hinder the insertion of the second connector 34 into the opening portion 38, similarly to the other suppression members 44 described above. In addition, since the suppression members 44C suppress the flow of air in the gap g, it is possible to suppress deterioration of the cooling efficiency of the electronic device 10, similarly to the other suppression members 44 described above. Since the suppression members 44C only need to suppress the flow of the air in the gap g, the suppression members 44C after being deformed and the second connector 34 may not be in contact with each other, for example.

Note that the original shape of the suppression members 44C shown in FIG. 9 is the same as that of the suppression members 44A of the first modification (see FIG. 5A). However, the shape of the suppression members 44 in the case where they have plasticity is not limited thereto, and for example, the shapes illustrated in the other drawings may be appropriately applied.

### Modification 4

Although the shape of the opening portion 38 of the faceplate 22 has been described as a quadrangular shape in the embodiment, the shape of the opening portion 38 is not limited to a quadrangular shape. For example, the opening portion 38 may have an annular shape. In this case, the suppression member 44 may be provided so as to surround the opening portion 38.

### Inventions that can be Obtained from Embodiment

The inventions that can be grasped from the above-described embodiment and modifications will be described below.

### First Invention

Provided is the faceplate (22) to which the circuit board (20) is attached and which covers the opening (24a) of the slot (24) of the electronic device (10) when the circuit board (20) is inserted into the slot (24), the faceplate including: the main body plate (36) configured to cover the opening (24a) of the slot (24); the opening portion (38) which is formed in the main body plate (36) and into which the connection surface side (34a) of the connector (34) provided on the circuit board (20) is inserted to expose the connection surface side (34a) of the connector (34); and the suppression member (44, 44A to 44C) configured to suppress the flow of air in the gap (g) formed between the opening portion (38) and the connector (34).

According to this feature, the faceplate (22) that suppresses the flow of air flowing into and out of the electronic device (10) through the gap (g) is provided.

The suppression member (44) may include the extending portion (46) extending from the main body plate (36) toward the inside of the electronic device (10) in the direction of insertion of the circuit board (20) into the slot (24), and the protruding portion (48) protruding from the extending portion (46) toward the connector (34). According to this feature, it is possible to restrict the passage of air entering the electronic device (10) through the gap (g).

The suppression member (44A) may be provided so as to extend from the edge (38e) of the opening portion (38) toward the connector (34). According to this feature, it is possible to restrict the passage of air entering the electronic device (10) through the gap (g).

The suppression member (44B) may extend from the main body plate (36) toward the inside of the electronic device (10) and have a curved shape in a manner so that the intermediate portion (44Ba) thereof protrudes toward the connector (34). According to this feature, the suppression member (44B) restricts the passage of air entering the electronic device (10) through the gap (g) and is less likely to hinder the operation of inserting the connector (34) into the opening portion (38).

The suppression member (44) may have elasticity and may be provided so as to interfere with the connector (34) when the connector (34) is inserted into the opening portion (38). According to this feature, the suppression member (44) restricts the passage of air entering the electronic device (10) through the gap (g) and, due to its deformation, is less likely to hinder the operation of inserting the connector (34) into the opening portion (38).

The suppression member (44C) may have plasticity and may be provided so as to interfere with the connector (34) when the connector (34) is inserted into the opening portion (38). According to this feature, the suppression member (44C) restricts the passage of air entering the electronic device (10) through the gap (g) and, due to its deformation, is less likely to hinder the operation of inserting the connector (34) into the opening portion (38).

The opening portion (38) may have a quadrangular shape, and the suppression member (44) may be provided for each of the four sides (38a to 38d) of the opening portion (38). According to this feature, the suppression member (44) can suitably suppress the flow of air in the gap (g) formed between the quadrangular opening portion (38) and the connector (34).

The opening portion (38) may have an annular shape, and the suppression member (44) may be provided so as to surround the opening portion (38). According to this feature, the suppression member (44) can suitably suppress the flow of air in the gap (g) formed between the annular opening portion (38) and the connector (34).

The end portion side of the circuit board (20) in the take-out direction opposite to the direction of insertion of the circuit board into the slot (24) may be attached to the faceplate (22). According to this feature, when the circuit board (20) is inserted into the slot (24), the faceplate (22) naturally covers the opening (24a) of the slot (24).

### Second Invention

Provided is the electronic device (10) including: the casing (16) provided with the intake opening (26) configured to take in the cooling air (A), the slot (24) into which the circuit board (20) to be cooled by the cooling air (A) is inserted, and the exhaust opening (28) through which the cooling air (A) having cooled the circuit board (20) is exhausted; and the faceplate (22) to which the circuit board (20) is attached, wherein the faceplate (22) includes: the main body plate (36) configured to cover the opening (24a) of the slot (24); the opening portion (38) which is formed in the main body plate (36) and into which the connection surface side (34a) of the connector (34) provided on the circuit board (20) is inserted to expose the connection surface side (34a) of the connector (34); and the suppression member (44) configured to suppress the flow of air in the gap (g) formed between the opening portion (38) and the connector (34).

According to this feature, the electronic device (10) provided with the faceplate (22) that suppresses the flow of air flowing into and out of the electronic device (10) through the gap (g) is provided.

### REFERENCE SIGNS LIST

10: electronic device
16: casing
20: circuit board
22: faceplate
24: slot
24a: opening
26: intake opening
28: exhaust opening
30: backboard
34: second connector (connector)
36: main body plate
38: opening portion
38a to 38d: side
38e: edge
44, 44A to 44C: suppression member
44Ba: intermediate portion
46: extending portion
48: protruding portion

1. A faceplate to which a circuit board is attached and which covers an opening of a slot of an electronic device when the circuit board is inserted into the slot, the faceplate comprising:
a main body plate configured to cover an opening of the slot;
an opening portion which is formed in the main body plate and into which a connection surface side of a connector provided on the circuit board is inserted to expose the connection surface side of the connector; and
a suppression member configured to suppress a flow of air in a gap formed between the opening portion and the connector.

2. The faceplate according to claim 1, wherein
the suppression member includes:
an extending portion extending from the main body plate toward an inside of the electronic device in a direction of insertion of the circuit board into the slot; and
a protruding portion protruding from the extending portion toward the connector.

3. The faceplate according to claim 1, wherein
the suppression member is provided so as to extend from an edge of the opening portion toward the connector.

4. The faceplate according to claim 3, wherein
the suppression member extends from the main body plate toward an inside of the electronic device and has a curved shape in a manner so that an intermediate portion of the suppression member protrudes toward the connector.

5. The faceplate according to claim 1, wherein
the suppression member has elasticity and is provided so as to interfere with the connector when the connector is inserted into the opening portion.

6. The faceplate according to claim 1, wherein
the suppression member has plasticity and is provided so as to interfere with the connector when the connector is inserted into the opening portion.

7. The faceplate according to claim 1, wherein
the opening portion has a quadrangular shape, and
the suppression member is provided for each of four sides of the opening portion.

8. The faceplate according to claim 1, wherein
the opening portion has an annular shape, and
the suppression member is provided so as to surround the opening portion.

9. The faceplate according to claim 1, wherein
an end portion side of the circuit board in a take-out direction opposite to a direction of insertion of the circuit board into the slot is attached to the faceplate.

10. An electronic device comprising:
a casing provided with an intake opening configured to take in cooling air, a slot into which a circuit board to be cooled by the cooling air is inserted, and an exhaust opening through which the cooling air having cooled the circuit board is exhausted; and
a faceplate to which the circuit board is attached,
wherein the faceplate includes:
a main body plate configured to cover an opening of the slot;
an opening portion which is formed in the main body plate and into which a connection surface side of a connector provided on the circuit board is inserted to expose the connection surface side of the connector; and
a suppression member configured to suppress a flow of air in a gap formed between the opening portion and the connector.
